(19) United States
(12) Patent Application Publication
(10) Pub. No.: US 2014/0071637 A1
(43) Pub. Date: Mar. 13, 2014

(54) TOUCH PANEL AND TOUCH DISPLAY DEVICE

(71) Applicants: WINTEK CORPORATION, Taichung City (TW); Wintek (China) Technology Ltd., Dongguan City (CN)

(72) Inventors: Chang-Hsuan Hsu, Changhua County (TW); Wen-Chun Wang, Taichung City (TW); Cheng-Yi Chou, Yunlin County (TW); Heng-Yi Chang, Taipei City (TW); Chien-Chung Chen, Taichung City (TW); Ching-Fu Hsu, Taichung City (TW); Chong-Wei Li, Changhua County (TW); Ting-Yu Chang, Kaohsiung City (TW); Kuo-Chang Su, Taichung City (TW)

(73) Assignees: WINTEK CORPORATION, Taichung City (TW); Wintek (China) Technology Ltd., Dongguan City (CN)

(21) Appl. No.: 14/019,528

(22) Filed: Sep. 5, 2013

(30) Foreign Application Priority Data
Sep. 7, 2012 (TW) 101132793

(51) Int. Cl. H05K 1/02

(52) U.S. Cl. CPC H05K 1/0213
USPC 361/748; 174/250

(57) ABSTRACT

A touch panel includes a first substrate and a first composite material conductive layer. The first composite material conductive layer has a first multilayer structure. The first multilayer structure includes a first refraction index compensating layer, a second refraction index compensating layer, and a first metal conductive layer. The first refraction index compensating layer, the first metal conductive layer, and the second compensation layer are stacked on the first substrate, and an equivalent refraction index of the first composite material conductive layer is substantially between a refraction index of the first substrate and 1.1 times the refraction index of the first substrate.

### BACKGROUND OF THE INVENTION

1. Field of the Invention

The present disclosure relates to a touch panel and a touch display device, and more particularly, to a touch panel and a touch display device with a composite material conductive layer having a multilayer structure to form sensing electrodes.

2. Description of the Prior Art

In touch panels, transparent conductive materials with both low resistance and high light transmittance are generally employed to form touch sensing units in order to prevent the touch sensing units from impacting the display quality of the touch panels. Currently, indium tin oxide (ITO) is the common transparent conducive material used in the field. Although the resistance of indium tin oxide is low and the light transmittance of indium tin oxide is high, in practical processes, indium tin oxide has to be crystallized at high temperature for achieving better resistance performance. In other words, the electrical impedance of indium tin oxide in amorphous state is too high to offer an application-oriented approach when applied alone. In this case, owing to the incapacity to withstand high temperatures, various substrates, such as plastic substrates, can not combine well with indium tin oxide formed by the deposition processes at high temperature. Accordingly, the method of forming the transparent conductive materials becomes a problem of the low temperature manufactured touch panel.

### SUMMARY OF THE INVENTION

It is one of the objectives of the disclosure to provide a touch panel and a touch display device. In the touch panel and the touch display device, a composite material conductive layer with two refraction index compensating layers and a metal conductive layer interposed in between is employed to form sensing electrodes, thereby reducing the resistance effectively and improving the light transmittance.

To achieve the purposes described above, an embodiment of the disclosure provides a touch panel. The touch panel includes a first substrate and a first composite material conductive layer. The first composite material conductive layer is disposed on the first substrate. The first composite material conductive layer comprises a plurality of first sensing electrodes. The first composite material conductive layer has a first multilayer structure. The first multilayer structure includes a first refraction index compensating layer, a second refraction index compensating layer, and a first metal conductive layer. The first refraction index compensating layer, the first metal conductive layer, and the second compensation layer are stacked on the first substrate so that an equivalent refraction index of the first composite material conductive layer is substantially between a refraction index of the first substrate and 1.1 times the refraction index of the first substrate.

To achieve the purposes described above, an embodiment of the disclosure provides a touch panel. The touch panel includes a first substrate, a display substrate, a display unit and a first composite material conductive layer. The display substrate is disposed opposite to the first substrate. The display unit is disposed on the display substrate. The first composite material conductive layer is disposed on the first substrate. The first composite material conductive layer comprises a plurality of first sensing electrodes. The first composite material conductive layer has a first multilayer structure. The first multilayer structure includes a first refraction index compensating layer, a second refraction index compensating layer, and a first metal conductive layer. The first refraction index compensating layer, the first metal conductive layer, and the second compensation layer are stacked on the first substrate so that an equivalent refraction index of the first composite material conductive layer is substantially between a refraction index of the first substrate and 1.1 times the refraction index of the first substrate.

To achieve the purposes described above, an embodiment of the disclosure provides a touch panel. The touch panel includes a first substrate and a first composite material conductive layer. The first composite material conductive layer is disposed on the first substrate. The first composite material conductive layer comprises a plurality of first sensing electrodes. The first composite material conductive layer has a first multilayer structure. The first multilayer structure includes a first refraction index compensating layer and a first metal conductive layer. The first refraction index compensating layer and the first metal conductive layer are stacked on the first substrate. A thickness of the first refraction index compensating layer is in a range between 30 nanometers and 80 nanometers. A thickness of the first metal conductive layer is in a range between 5 nanometers and 20 nanometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a touch panel according to a first embodiment of the present invention.

FIG. 2 is a top-view schematic diagram illustrating the touch panel according to the first embodiment of the present invention.

FIG. 3 is a schematic diagram illustrating a touch panel according to another embodiment of the present invention.

FIG. 4 is a schematic diagram illustrating a touch panel according to another embodiment of the present invention.

FIG. 5 is a schematic diagram illustrating a touch panel according to another embodiment of the present invention.

FIG. 6 is a schematic diagram illustrating a touch panel according to another embodiment of the present invention.

FIG. 7 is a schematic diagram illustrating a touch panel according to a second embodiment of the present invention.

FIG. 8 is a schematic diagram illustrating a touch panel according to a third embodiment of the present invention.

FIG. 9 is a top-view schematic diagram illustrating a portion of the touch panel according to the third embodiment of the present invention.

FIG. 10 is a schematic diagram illustrating a touch panel according to a fourth embodiment of the present invention.

FIG. 11 is a schematic diagram illustrating a touch panel according to a fifth embodiment of the present invention.

FIG. 12 is a top-view schematic diagram illustrating the touch panel according to the fifth embodiment of the present invention.

FIG. 13 is a schematic diagram illustrating a touch panel according to another embodiment of the present invention.

FIG. 14 is a schematic diagram illustrating a touch panel according to a sixth embodiment of the present invention.

FIG. 15 is a schematic diagram illustrating a touch panel according to another embodiment of the present invention.

FIG. 16 is a schematic diagram illustrating a touch display device according to a seventh embodiment of the present invention.

FIG. 17 is a schematic diagram illustrating a touch display device according to another embodiment of the present invention.

FIG. 18 is a schematic diagram illustrating a touch display device according to an eighth embodiment of the present invention.

FIG. 19 is a schematic diagram illustrating a touch display device according to another embodiment of the present invention.

FIG. 20 is a schematic diagram illustrating a touch display device according to a ninth embodiment of the present invention.

FIG. 21 is a schematic diagram illustrating a touch display device according to another embodiment of the present invention.

FIG. 22 is a schematic diagram illustrating a touch display device according to a tenth embodiment of the present invention.

### DETAILED DESCRIPTION

To provide a better understanding of the present disclosure, features of the embodiments will be made in detail. The embodiments of the present disclosure are illustrated in the accompanying drawings with numbered elements.

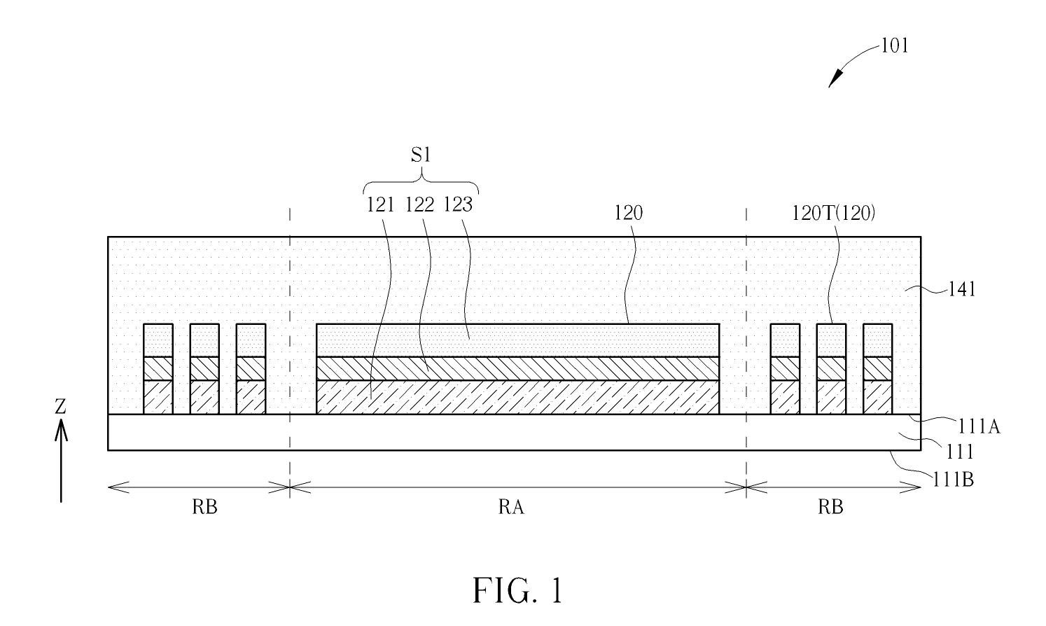

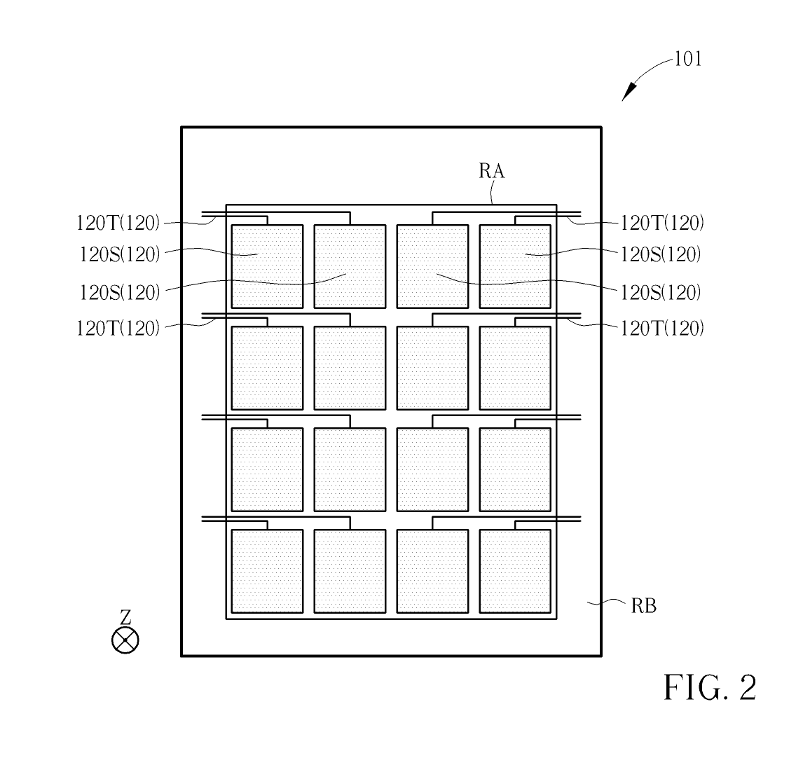

Please refer to FIGS. 1-2. FIG. 1 is a schematic diagram illustrating a touch panel according to a first embodiment of the present invention. FIG. 2 is a top-view schematic diagram illustrating the touch panel according to the first embodiment of the present invention. For brevity purposes, please note that the figures are only for illustration and the figures may not be to scale. The scale maybe further modified according to different design considerations. As shown in FIGS. 1-2, a touch panel 101 is provided in this embodiment. The touch panel 101 includes a first substrate 111 and a first composite material conductive layer 120. The first composite material conductive layer 120 is disposed on the first substrate 111. In this embodiment, the first substrate 111 has a first surface 111A and a second surface 111B. The first composite material conductive layer 120 is disposed on the first surface 111A, but not limited thereto. In addition, the first substrate 111 may included a hard substrate, such as a glass substrate and a cover glass, a flexible substrate/film substrate, such as a plastic substrate, or a substrate formed of other suitable materials. Preferably, the first substrate 111 is a plastic substrate, but not limited thereto. The first composite material conductive layer 120 comprises a plurality of first sensing electrodes 120S. The first composite material conductive layer 120 has a first multilayer structure S1. The first multilayer structure S1 includes a first refraction index compensating layer 121, a second refraction index compensating layer 123 and a first metal conductive layer 122 disposed between the first refraction index compensating layer 121 and the second refraction index compensating layer 123. The first refraction index compensating layer 121, the first metal conductive layer 122, and the second refraction index compensating layer 123 are stacked in that order from bottom to top on the first substrate 111. In this way, the equivalent refraction index of the first composite material conductive layer 120 is substantially between the refraction index of the first substrate 111 and 1.1 times the refraction index of the first substrate 111. Besides, the thickness of the first refraction index compensating layer 121 is in a range between 30 nm (nanometers) and 80 nm. The thickness of the second refraction index compensating layer 123 is in a range between 30 nm and 80 nm. The thickness of first metal conductive layer 122 is in a range between 5 nm and 20 nm. However, the present invention is not limited to this. For example, in one case, to improve the overall light transmittance of both the first substrate 111 and the first composite material conductive layer 120, the thickness of both the first refraction index compensating layer 121 and the second refraction index compensating layer 123 are respectively 50 nm, and the thickness of the first metal conductive layer 122 is 10 nm. In another case, to improve the overall light transmittance of both the first substrate 111 and the first composite material conductive layer 120, the thickness of the first refraction index compensating layer 121 is either 40 nm (when the thickness of the second refraction index compensating layer 123 is 60 nm) or 60 nm (when the thickness of the second refraction index compensating layer 123 is 40 nm), and the thickness of the first metal conductive layer 122 is 10 nm. It is worth noting that the present invention is not limited to the thickness ranges mentioned above, and the thickness of the first refraction index compensating layer 121, the thickness of the second refraction index compensating layer 123 and the thickness of the first metal conductive layer 122 may be further modified according to other considerations of material or optical properties.

More specifically, in this embodiment, the material of the first metal conductive layer 122 may include metallic materials, for example, but not limited to, at least one among silver (Ag), aluminum (Al), copper (Cu), chromium (Cr), titanium (Ti), molybdenum (Mo), an alloy thereof, a composite layer thereof, or a composite layer of the above-mentioned materials and alloys. Preferably, the first metal conductive layer 122 is silver, but not limited thereto. By controlling the thickness of the first metal conductive layer 122—for example, the first metal conductive layer 122 is controlled within a nanometer level—the light transmittance of the first metal conductive layer 122 can be improved and a considerable electrical conductivity is maintained. Nevertheless, even in this case, the refractive index of the first metal conductive layer 122 is still high. Therefore, the first refraction index compensating layer 121 and the second refraction index compensating layer 123, which are disposed on the opposite sides of the first metal conductive layer 122, are required to match the first metal conductive layer 122 (i.e., to be suitable for the first metal conductive layer 122) so that the equivalent refraction index of the first composite material conductive layer 120 may be substantially between the refraction index of the first substrate 111 and 1.1 times the refraction index of the first substrate 111. The refractive index of both the first refraction index compensating layer 121 and the second refraction index compensating layer 123 is preferably greater than the refractive index of the first metal conductive layer 122 so that the equivalent refraction index of the first composite material conductive layer 120 is substantially between the refraction index of the first substrate 111 and 1.1 times the refraction index of the first substrate 111. Nevertheless, the present invention is not limited to this—both the first refraction index compensating layer 121 and the second refraction index compensating layer 123 with a refractive index lower than that of the first metal conductive layer 122 may also be employed according to other considerations, if the overall light transmittance is improved and the aimed visual effect is ensured. For example, the refractive index of both the first refraction index compensating layer 121 and the second refraction index compensating layer 123 is preferably in a range between 1.5 and 3, although the exact thickness of the first refraction index compensating layer 121, the exact thickness of the second refraction index compensating layer 123 and the exact thickness of the first metal conductive layer 122 may be further modified according to other considerations so as to meet the required electrical properties and the required optics compensation effect.

The first refraction index compensating layer 121 in this embodiment preferably comprises a transparent conductive layer, a transparent semiconductor layer or a transparent insulation layer. The second refraction index compensating layer 123 also preferably comprises a transparent conductive layer, a transparent semiconductor layer or a transparent insulation layer. Accordingly, the combined effects of the first refraction index compensating layer 121, the second refraction index compensating layer 123 and the first metal conductive layer 122 may effectively reduce the electrical impedance and improve the light transmittance. The preceding transparent conductive layer may preferably comprise indium tin oxide (ITO), indium zinc oxide (IZO) and aluminum zinc oxide (AZO) or other suitable transparent conductive materials. The preceding transparent semiconductor layer may preferably comprise zinc oxide (ZnO), zinc magnesium oxide (ZnMgO), indium gallium zinc oxide (IGZO), antimony tin oxide (ATO, sometimes also referred to as stannum stibium oxide, SnSbO2), zinc selenium oxide (ZnSeO), zinc zirconium oxide (ZnZrO) or other suitable transparent semiconductor materials. The preceding transparent insulation layer may preferably comprise oxides, such as titanium oxide (TiO₂) and silicon oxide (SiOx), nitrides, such as silicon nitride (SiNx), or other suitable transparent insulation materials. The material of the first refraction index compensating layer 121 and the material of the second refraction index compensating layer 123 maybe the same or different according to the requirements. In other words, the first multilayer structure S1 may consist of the first metal conductive layer 122 and two transparent conductive layers respectively on and below the first metal conductive layer 122. Alternatively, the first multilayer structure S1 may consist of the first metal conductive layer 122 and two transparent semiconductor layers respectively on and below the first metal conductive layer 122. Alternatively, the first multilayer structure S1 may consist of the first metal conductive layer 122 and two transparent insulation layers respectively on and below the first metal conductive layer 122. Alternatively, the first multilayer structure S1 may consist of the first metal conductive layer 122, a transparent conductive layer and a transparent insulation layer. Alternatively, the first multilayer structure S1 may consist of the first metal conductive layer 122, a transparent conductive layer and a transparent semiconductor layer. Alternatively, the first multilayer structure S1 may consist of the first metal conductive layer 122, a transparent semiconductor layer and a transparent insulation layer. However, the present invention is not limited to these. It is worth noting that the first metal conductive layer 122 determines the electrical conductivity in the first composite material conductive layer 120, so the electrical impedance requirement of the transparent conductive layers, which correspond to the first metal conductive layer 122, is lower. In other words, although the electrical impedance of the transparent conductive materials formed without high temperature process is relatively high, the transparent conductive materials, for example, but not limited to, indium tin oxide (ITO) in the amorphous (or non-crystalline) state, can still be employed to form the first refraction index compensating layer 121 and the second refraction index compensating layer 123 in this embodiment. Therefore, the touch panel 101 maybe fabricated with low temperature processes. For example, if the first substrate 111 is a plastic substrate, the first refraction index compensating layer 121 must be formed by low temperature processes. At the same time, the electrical impedance of the first refraction index compensating layer 121, such as indium tin oxide (ITO), formed by low temperature processes is high. Nevertheless, in the present invention, the first metal conductive layer 122 is connected to the first refraction index compensating layer 121 completely in parallel so as to achieve the required electrical impedance. In addition, for large-size display panels, since the length of the electrodes becomes longer as the size of the touch panels is enlarged, the requirement of the electrical impedance becomes stricter. The desired electrical impedance can be obtained by coordinating the material of both the first metal conductive layer 122 and the first refraction index compensating layer 121, such as indium tin oxide (ITO).

In this embodiment, the first refraction index compensating layer 121 is disposed between the first substrate 111 and the first metal conductive layer 122. The first refraction index compensating layer 121, the first metal conductive layer 122 and the second refraction index compensating layer 123 are stacked in that order from bottom to top on the first substrate 111 in a vertical projection direction Z perpendicular to the first substrate 111. Since the first composite material conductive layer 120 is required to be electrically connected to other components, the second refraction index compensating layer 123 is preferably a transparent conductive layer, but not limited thereto. The touch panel 101 in this embodiment may further include a protective layer 141 that covers the first composite material conductive layer 120.

As shown in FIGS. 1-2, the touch panel 101 in this embodiment has a touch sensing region RA and a peripheral region RB disposed on at least one side of the touch sensing region RA. A part of the first sensing electrodes 120S are disposed in the touch sensing region RA. A decoration layer (not shown in FIGS. 1-2) is formed in at least a portion of the peripheral region RB on the first substrate 111. Preferably, the first sensing electrodes 120S in this embodiment are separately disposed in the touch sensing region RA so as to detect touch sensing signals. Besides, the first composite material conductive layer 120 may further comprise a plurality of trace lines 120T disposed in the peripheral region RB. Each of the trace lines 120T is electrically connected to each of the first sensing electrodes 120S (i.e., the first sensing electrodes 120S corresponding to the trace lines 120T). It is worth noting that because the trace lines 120T and the first sensing electrodes 120S are formed out of the first composite material conductive layer 120, the fabrication process may be simplified. In this way, the electrical connection between the trace lines 120T and the first sensing electrodes 120S is assured; on the contrary, the electrical connection between the trace lines 120T and the first sensing electrodes 120S may be poor if the trace lines 120T and the first sensing electrodes 120S are formed out of different materials. Each of the first sensing electrodes 120S in this embodiment is preferably a rectangular electrode. However, the present invention is not limited to this and sensing electrodes of different shapes, for example, but not limited to, triangular sensing electrodes, may also be arranged in the touch sensing region RA so as to ensure the touch sensing function according to other considerations.

Other embodiments or modifications of the present invention will be detailed in the following description. In order to simplify and show the differences or modifications between the following embodiments and the above-mentioned embodiment, the same numerals denote the same components in the following description, and the similar parts are not detailed redundantly.

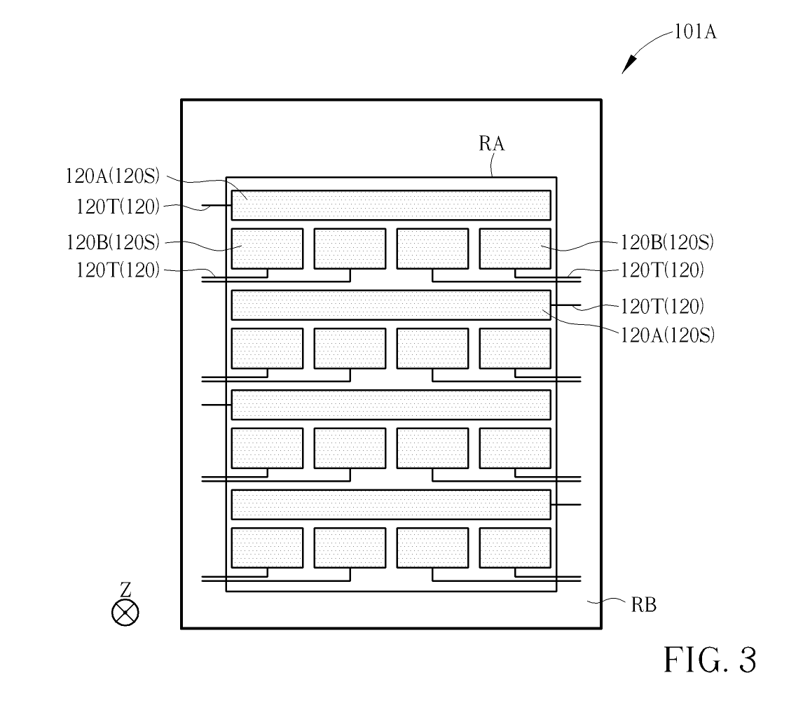

Please refer to FIG. 3. FIG. 3 is a schematic diagram illustrating a touch panel according to another embodiment of the present invention. As shown in FIG. 3, in the touch panel 101A of this embodiment, the first sensing electrodes 1205 further include a plurality of signal transmitting electrodes 120A and a plurality of signal receiving electrodes 120B. The signal transmitting electrodes 120A and the signal receiving electrodes 120B are configured to transmit touch sensing signals and receive touch sensing signals respectively. In other words, the touch panel 101A may serve as a mutual capacitive touch panel, but not limited thereto. Apart from the signal transmitting electrodes 120A and the signal receiving electrodes 120B in the touch panel 101A in this embodiment, features, locations and material properties of other components in this embodiment are similar to those in the first embodiment detailed above and will not be redundantly described.

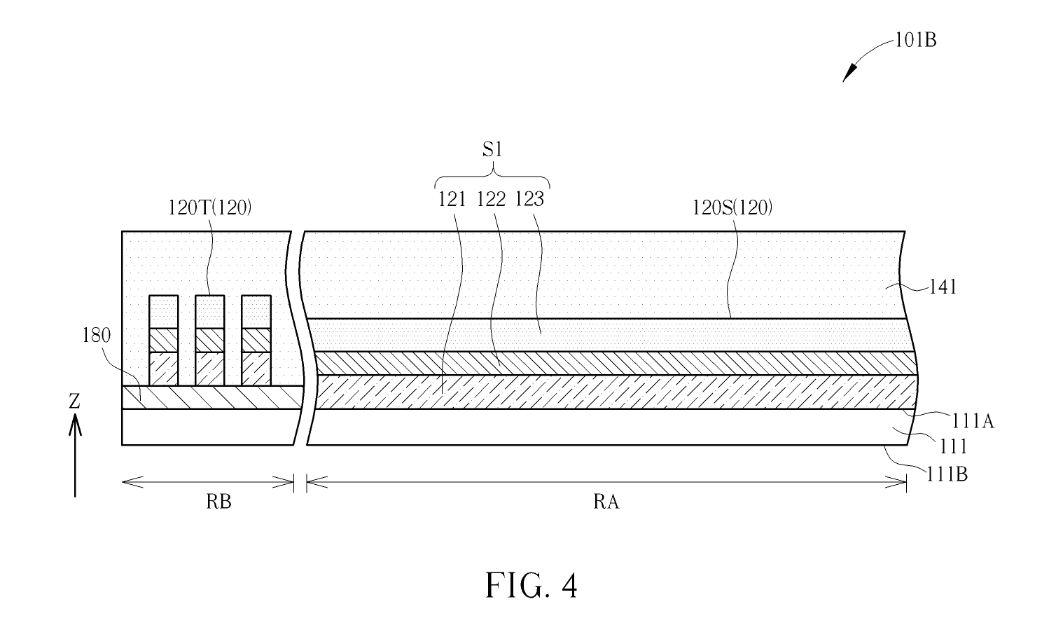

Please refer to FIG. 4. FIG. 4 is a schematic diagram illustrating a touch panel according to another embodiment of the present invention. As shown in FIG. 4, the touch panel 101B in this embodiment may further include the decoration layer 180 disposed in the peripheral region RB. The decoration layer 180 is preferably disposed between the trace lines 120T and the first substrate 111. In addition, in other embodiments of the present invention, the touch sensing region RA may also extend to the decoration layer 180 according to other considerations. Moreover, the decoration layer 180 may be also disposed between a portion of the first sensing electrodes 120S and the first substrate 111 according to other considerations. In other words, the decoration layer 180 is formed in the peripheral region RB on the first substrate 111. Apart from the decoration layer 180 in the touch panel 101B in this embodiment, features, locations and material properties of other components in this embodiment are similar to those in the first embodiment detailed above and will not be redundantly described.

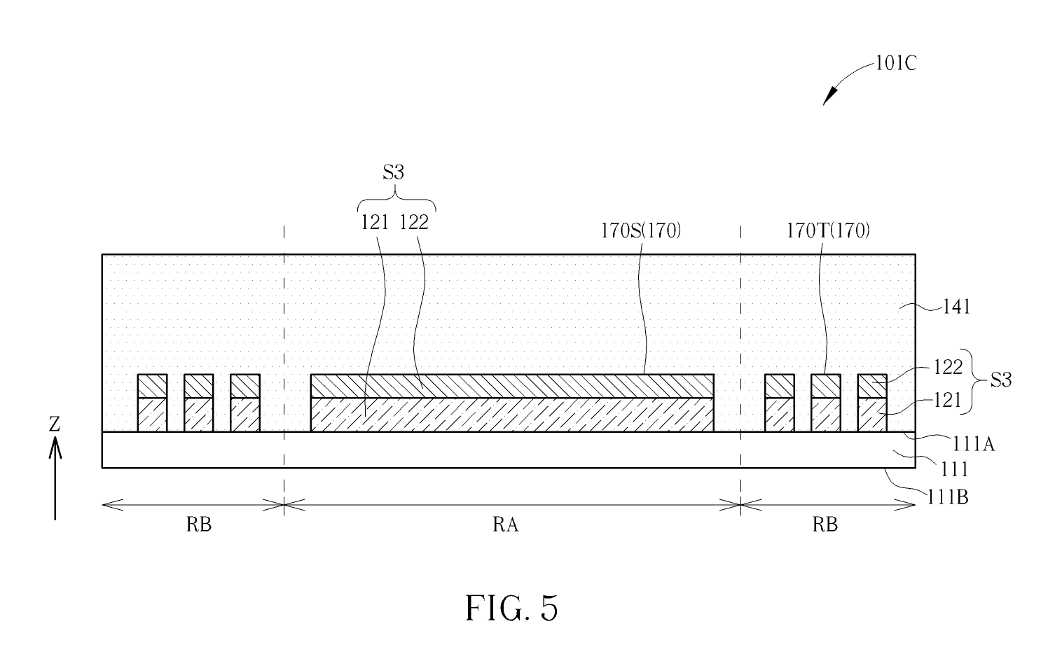

Please refer to FIG. 5. FIG. 5 is a schematic diagram illustrating a touch panel according to another embodiment of the present invention. As shown in FIG. 5, the touch panel 101C in this embodiment of the present invention includes a first substrate 111 and a first composite material conductive layer 170. The first composite material conductive layer 170 is disposed on the first surface 111A of the first substrate 111. The first composite material conductive layer 170 includes a plurality of first sensing electrodes 170S and a plurality of trace lines 170T. The first sensing electrodes 170S and the trace lines 170T are respectively disposed in the touch sensing region RA and in the peripheral region RB. The first composite material conductive layer 170 has a first multilayer structure S3. The first multilayer structure S3 includes a first refraction index compensating layer 121 and a first metal conductive layer 122. The first refraction index compensating layer 121 and the first metal conductive layer 122 are stacked in that order from bottom to top on the first substrate 111 so that the equivalent refraction index of the first composite material conductive layer 170 is substantially between the refraction index of the first substrate 111 and 1.1 times the refraction index of the first substrate 111. In other words, the first multilayer structure S3 in this embodiment is preferably a dual-layered (or double-layered) structure. Owing to the first refraction index compensating layer 121 disposed, the equivalent refraction index of the first composite material conductive layer 170 is substantially between the refraction index of the first substrate 111 and 1.1 times the refraction index of the first substrate 111. It is worth noting that the thickness of the first refraction index compensating layer 121 is preferably in a range between 30 nm and 80 nm. The thickness of first metal conductive layer 122 is preferably in a range between 5 nm and 20 nm to match the first refraction index compensating layer 121 (i.e., to be suitable for the first refraction index compensating layer 121). In addition, the first refraction index compensating layer 121 in this embodiment is disposed between the first substrate 111 and the first metal conductive layer 122. In this case, the thickness of the first refraction index compensating layer 121 is preferably 60 nm. The thickness of first metal conductive layer 122 is preferably 10 nm. The overall light transmittance of both the first substrate 111 and the first composite material conductive layer 170 can therefore be improved thanks to this coordinated approach, but not limited thereto. Apart from the first multilayer structure S3 being preferably a dual-layered structure in this embodiment, features, locations and material properties of other components in this embodiment are similar to those in the first embodiment detailed above and will not be redundantly described.

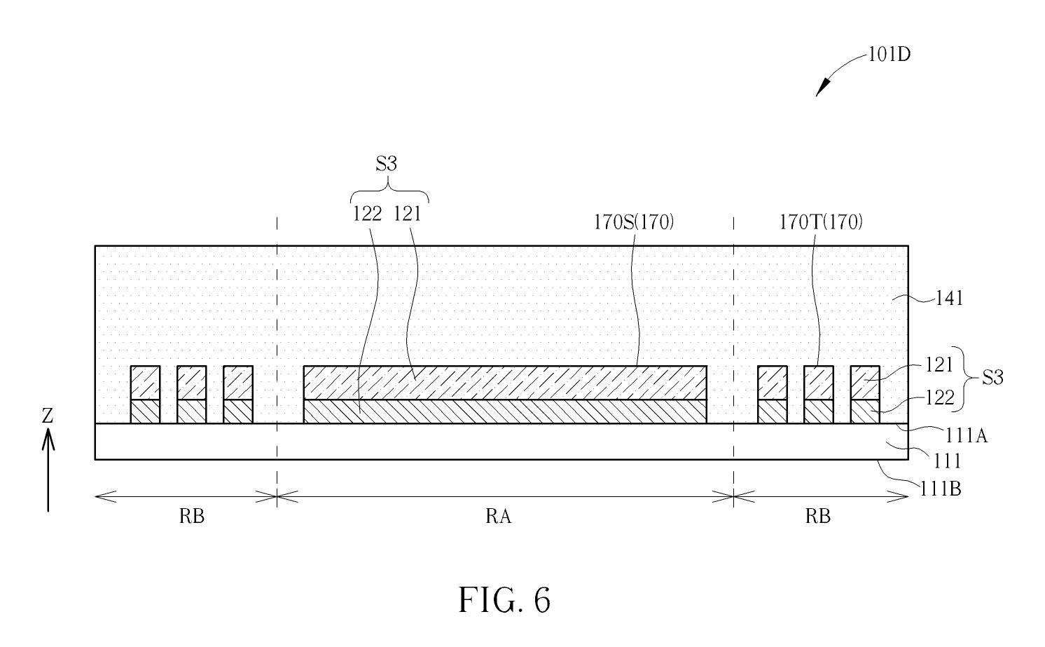

Please refer to FIG. 6. FIG. 6 is a schematic diagram illustrating a touch panel according to another embodiment of the present invention. As shown in FIG. 6, the difference between the touch panel 101D of this embodiment and the touch panel of the preceding embodiment is that the first metal conductive layer 122 in this embodiment is disposed between the first substrate 111 and the first refraction index compensating layer 121. In this case, the thickness of the first refraction index compensating layer 121 is preferably 40 nm. The thickness of first metal conductive layer 122 is preferably 10 nm. The overall light transmittance of both the first substrate 111 and the first composite material conductive layer 170 can therefore be improved thanks to this coordinated approach but not limited thereto. Apart from the locations of the first metal conductive layer 122 and the first refraction index compensating layer 121 in the first multilayer structure S3, features, locations and material properties of other components in this embodiment are similar to those of the touch panel 101C in the embodiment detailed above and will not be redundantly described.

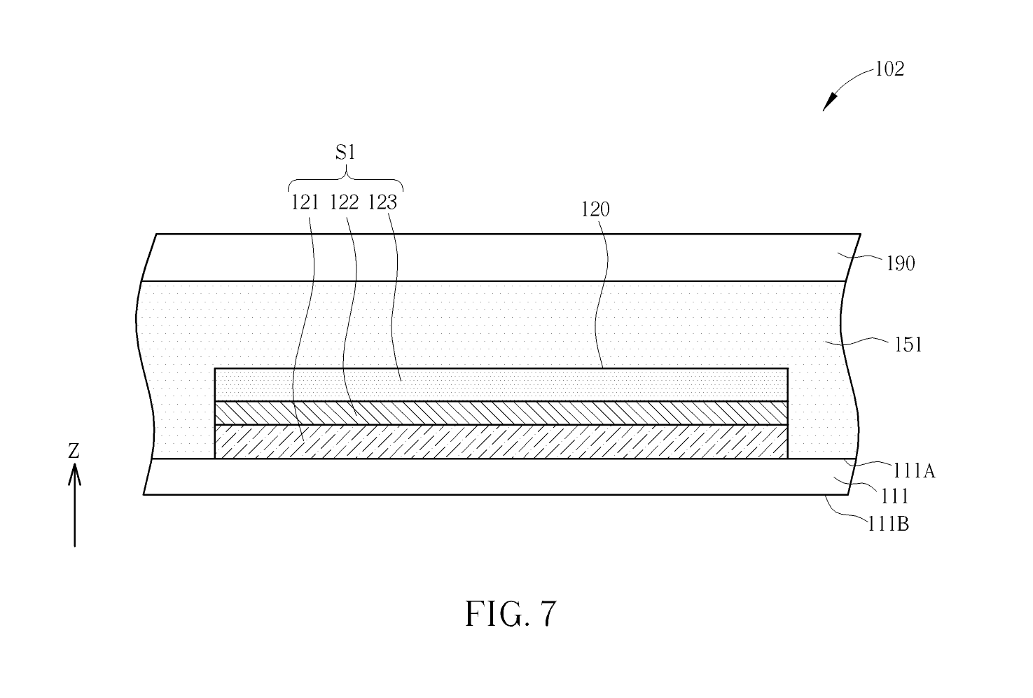

Please refer to FIG. 7. FIG. 7 is a schematic diagram illustrating a touch panel according to a second embodiment of the present invention. As shown in FIG. 7, the difference between the touch panel 102 of the second embodiment in the present invention and the touch panel of the preceding first embodiment is that the touch panel 102 further includes a cover substrate 190 and an adhesive layer 151. The adhesive layer 151 is disposed between the cover substrate 190 and the first substrate 111 so as to attach the cover substrate 190 to the first substrate 111. Apart from the cover substrate 190 and the adhesive layer 151 in this embodiment, features, locations and material properties of other components in this embodiment are similar to those of in the first embodiment detailed above and will not be redundantly described. It is worth noting that the refractive index of the second refraction index compensating layer 123 in this embodiment is preferably in a range between the refractive index of the first metal conductive layer 122 and the refractive index of the adhesive layer 151 so as to achieve higher optical quality, but not limited thereto.

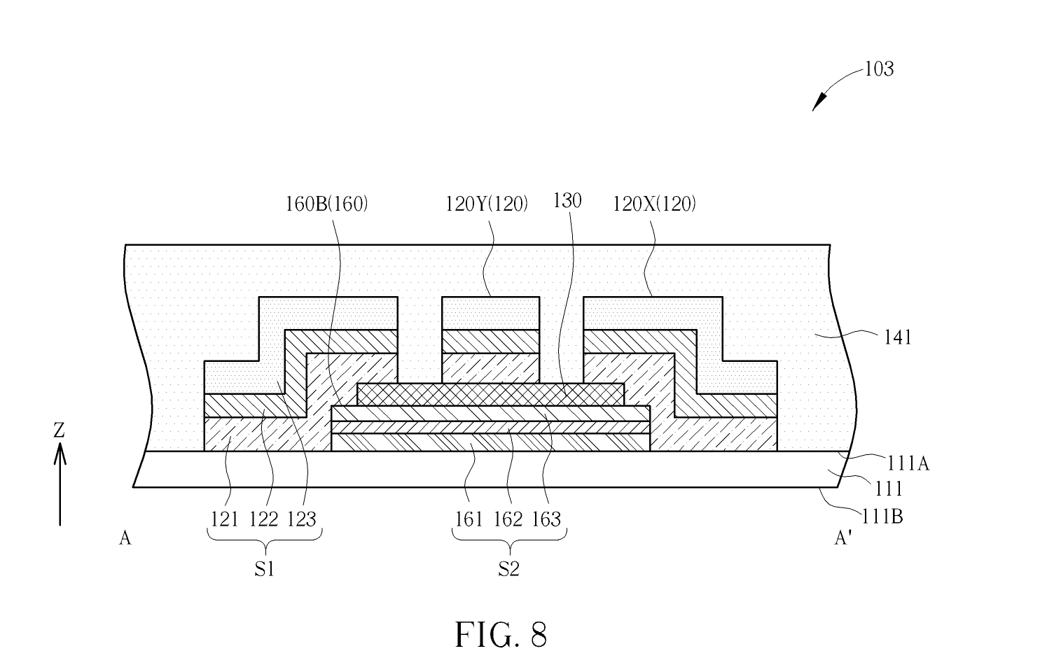

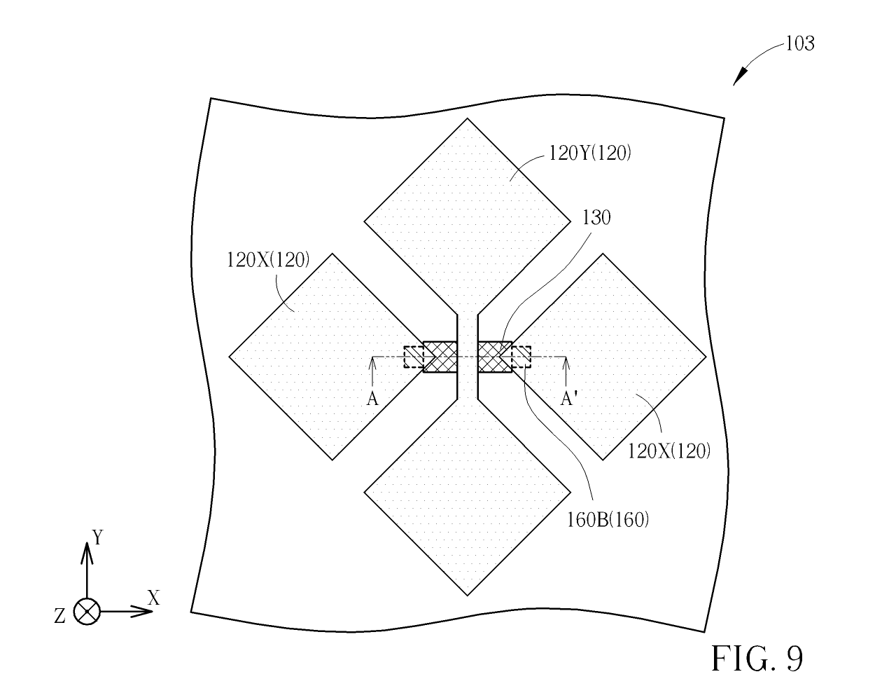

Please refer to FIGS. 8-9. FIG. 8 is a schematic diagram illustrating a touch panel according to a third embodiment of the present invention. FIG. 9 is a top-view schematic diagram illustrating a portion of the touch panel according to the third embodiment of the present invention. FIG. 8 can be regarded as a cross-sectional view diagram taken along a cross-sectional line A-A′ in FIG. 9. As shown in FIGS. 8-9, the difference between the touch panel 103 of the third embodiment in the present invention and the touch panel of the first embodiment is that the touch panel 103 further includes a second composite material conductive layer 160. The second composite material conductive layer 160 is disposed on the first substrate 111. The second composite material conductive layer 160 has a second multilayer structure S2. The second multilayer structure S2 comprises a third refraction index compensating layer 161, a fourth refraction index compensating layer 163 and a second metal conductive layer 162. The second metal conductive layer 162 is disposed between the third refraction index compensating layer 161 and the fourth refraction index compensating layer 163 so that the equivalent refraction index of the second composite material conductive layer 160 is substantially between the refraction index of the first substrate 111 and 1.1 times the refraction index of the first substrate 111. The third refraction index compensating layer 161 in this embodiment preferably comprises a transparent conductive layer, a transparent semiconductor layer or a transparent insulation layer. The fourth refraction index compensating layer 163 also preferably comprises a transparent conductive layer, a transparent semiconductor layer or a transparent insulation layer. The material of the third refraction index compensating layer 161 and the material of the fourth refraction index compensating layer 163 may be the same or different according to the requirements so that the combined effects of the third refraction index compensating layer 161, the fourth refraction index compensating layer 163 and the second metal conductive layer 162 may effectively reduce the electrical impedance and improve the light transmittance. In other words, the second composite material conductive layer 160 and the second multilayer structure S2 are similar to the above-mentioned first composite material conductive layer 120 and the above-mentioned first multilayer structure S1. Besides, the combined effects of both the thickness and the refractive index are also similar to the above-mentioned first composite material conductive layer 120. In other words, the thickness of the third refraction index compensating layer 161 is preferably in a range between 30 nm and 80 nm. The thickness of the fourth refraction index compensating layer 163 is preferably in a range between 30 nm and 80 nm. The thickness of the second metal conductive layer 162 is preferably in a range between 5 nm and 20 nm. Nevertheless, the present invention is not limited to this. For example, in one case, the thickness of both the third refraction index compensating layer 161 and the fourth refraction index compensating layer 163 are both 50 nm. The thickness of the second metal conductive layer 162 is 10 nm. In another case, the thickness of the third refraction index compensating layer 161 is either 40 nm (when the thickness of the fourth refraction index compensating layer 163 is 60 nm) or 60 nm (when the thickness of the fourth refraction index compensating layer 163 is 40 nm). The thickness of the second metal conductive layer 162 is 10 nm. It is worth noting that the present invention is not limited to the thickness ranges mentioned above and the thickness of the third refraction index compensating layer 161, the thickness of the fourth refraction index compensating layer 163 and the thickness of the second metal conductive layer 162 may be further modified according to other considerations of material or optical properties. It is worth noting that, in other embodiments of the present invention, the second multilayer structure S2 may be a dual-layered structure according to other considerations—i.e. the second multilayer structure S2 only includes the third refraction index compensating layer 161 and the second metal conductive layer 162—but not limited thereto. In the following embodiments, the first multilayer structure S1 and the second multilayer structure S2 are respectively regarded as a triple-layered structure, but not limited thereto. That is to say, in the following embodiments, both the first multilayer structure and the second multilayer structure may also be dual-layered structures consisting of a refraction index compensating layer and a metal conductive layer according to other considerations.

In this embodiment, the first composite material conductive layer 120 and the second composite material conductive layer 160 are disposed on the same side of the first substrate 111. The second composite material conductive layer 160 is disposed between the first substrate 111 and the first composite material conductive layer 120. The first composite material conductive layer 120 includes a plurality of first sensing electrodes 120X and a second sensing electrode 120Y. The second composite material conductive layer 160 includes a bridge electrode 160B. The bridge electrode 160B is used to electrically connect two of the adjacent first sensing electrodes 120X (i.e., the first sensing electrodes 120X adjacent to each other) in a first direction X. In addition, the touch panel 103 further comprises an insulation layer 130. The insulation layer 130 is disposed between the bridge electrode 160B and the second sensing electrode 120Y, which extends along a second direction Y so as to electrically isolate the second sensing electrode 120Y from the bridge electrode 160B. In addition, considering the resulting electrical connection between the first sensing electrodes 120X and the bridge electrode 160B, both the fourth refraction index compensating layer 163 and the first refraction index compensating layer 121 are preferably transparent conductive layers, but not limited thereto.

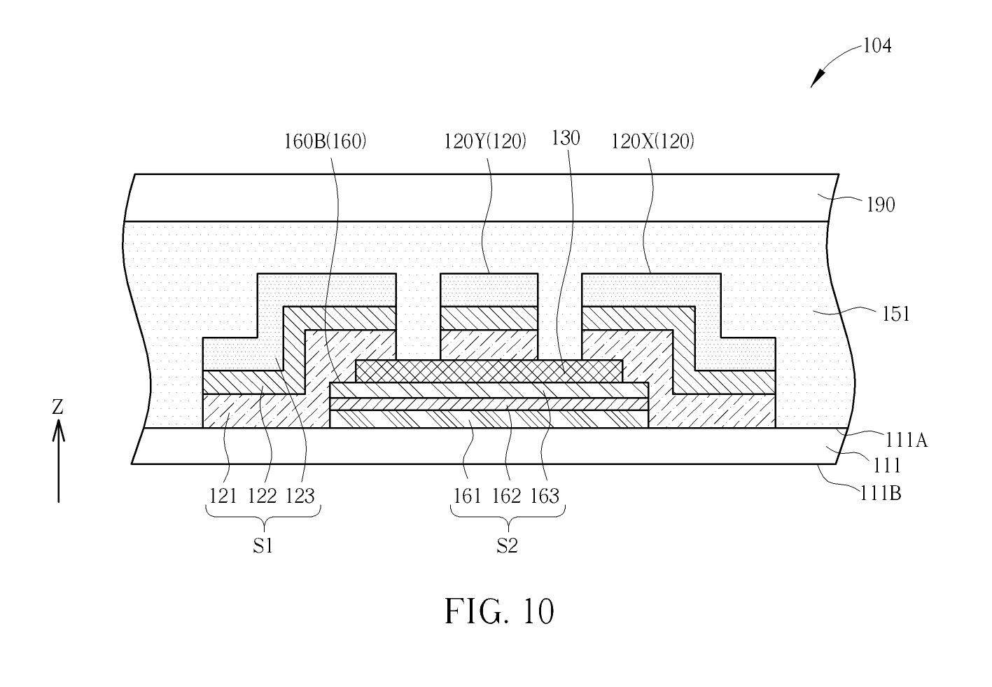

Please refer to FIG. 10. FIG. 10 is a schematic diagram illustrating a touch panel according to a fourth embodiment of the present invention. As shown in FIG. 10, the difference between the touch panel 104 of the fourth embodiment in the present invention and the touch panel of the preceding third embodiment is that the touch panel 104 further includes the cover substrate 190 and the adhesive layer 151. The adhesive layer 151 is disposed between the cover substrate 190 and the first substrate 111 so as to attach the cover substrate 190 to the first substrate 111. Apart from the cover substrate 190 and the adhesive layer 151 in the touch panel 104 of this embodiment, features, locations and material properties of other components in this embodiment are similar to those in the third embodiment detailed above and will not be redundantly described.

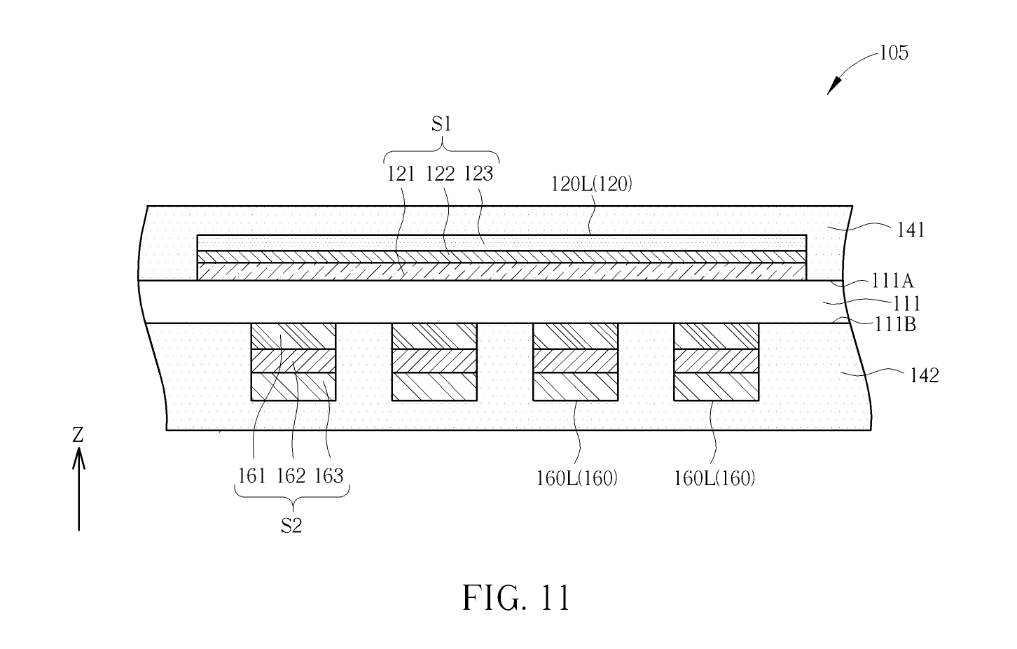

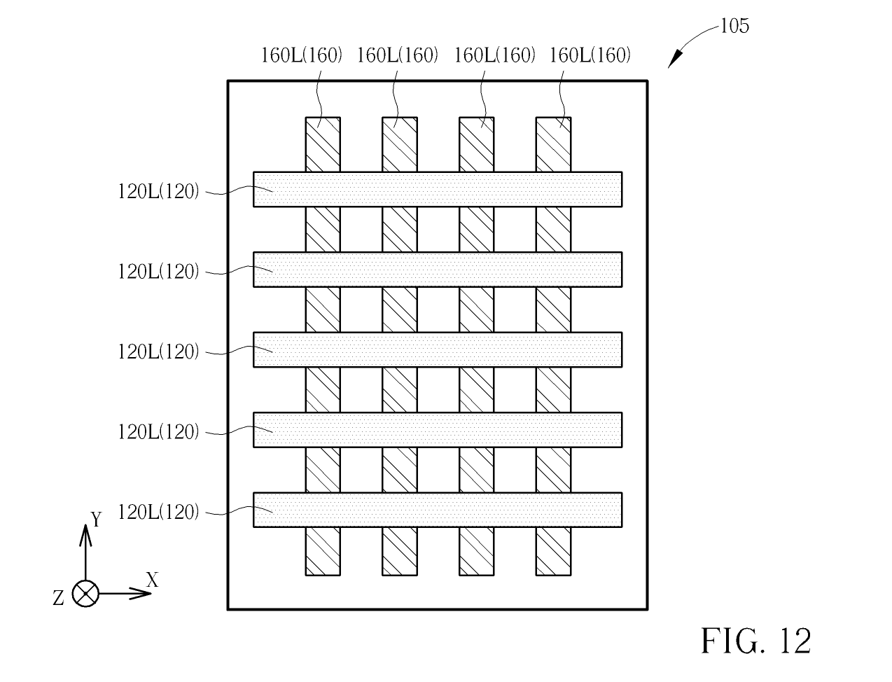

Please refer to FIGS. 11-12. FIG. 11 is a schematic diagram illustrating a touch panel according to a fifth embodiment of the present invention. FIG. 12 is a top-view schematic diagram illustrating the touch panel according to the fifth embodiment of the present invention. As shown in FIGS. 11-12, the difference between the touch panel 105 of the fifth embodiment and the touch panel of the preceding third embodiment is that the first composite material conductive layer 120 and the second composite material conductive layer 160 are respectively disposed on different sides of the first substrate 111 in the touch panel 105. More specifically, the first composite material conductive layer 120 is disposed on the first surface 111A of the first substrate 111. The second composite material conductive layer 160 is disposed on the second surface 111B of the first substrate 111. The substrate 111 can be a color filter substrate, which is a part of LCD panel. However, the present invention is not limited to this. It is worth noting that the second composite material conductive layer 160 can be omitted in this embodiment. In addition, the first composite material conductive layer 120 includes a plurality of first sensing electrodes 120L. The second composite material conductive layer 160 includes a plurality of second sensing electrodes 160L. Each of the first sensing electrodes 120L is preferably a stripe electrode extending along the first direction X, and each of the second sensing electrodes 160L is preferably a stripe electrode extending along the second direction Y, but not limited thereto. Moreover, the touch panel 105 may further include a protective layer 141 and a protective layer 142. The protective layer 141 and the protective layer 142 are respectively disposed on the first surface 111A and on the second surface 111B so as to cover the first sensing electrodes 120L and the second sensing electrodes 160L.

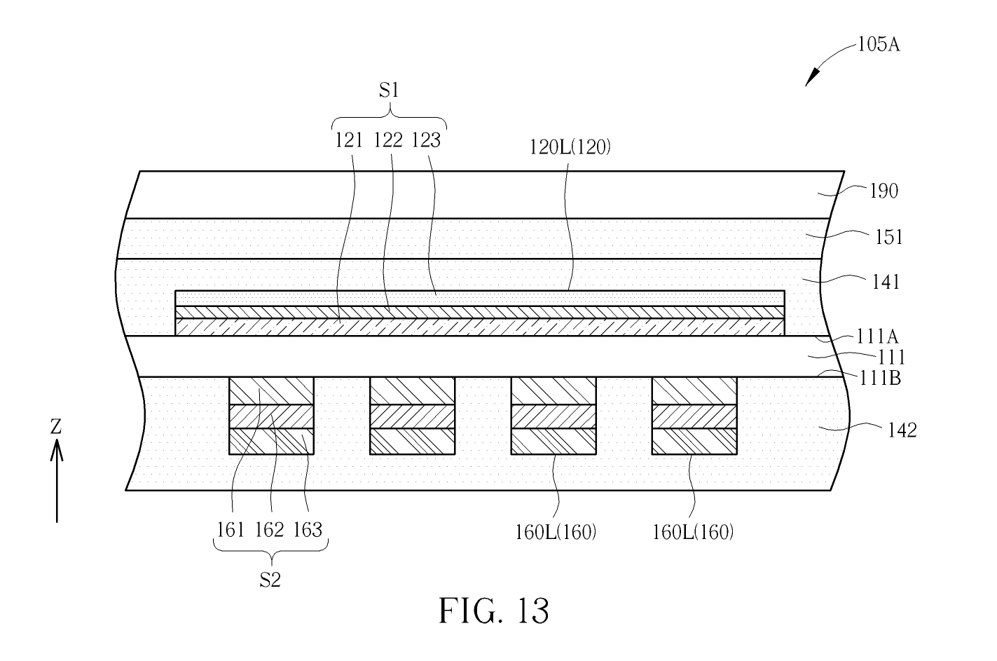

Please refer to FIG. 13. FIG. 13 is a schematic diagram illustrating a touch panel according to another embodiment of the present invention. As shown in FIG. 13, the difference between the touch panel 105A of this embodiment in the present invention and the touch panel of the preceding fifth embodiment is that the touch panel 105A further includes the cover substrate 190 and an adhesive layer 151. The adhesive layer 151 is disposed between the cover substrate 190 and the first substrate 111 so as to attach the cover substrate 190 to the first substrate 111. Apart from the cover substrate 190 and the adhesive layer 151 in the touch panel 105A of this embodiment, features, locations and material properties of other components in this embodiment are similar to those in the fifth embodiment detailed above and will not be redundantly described.

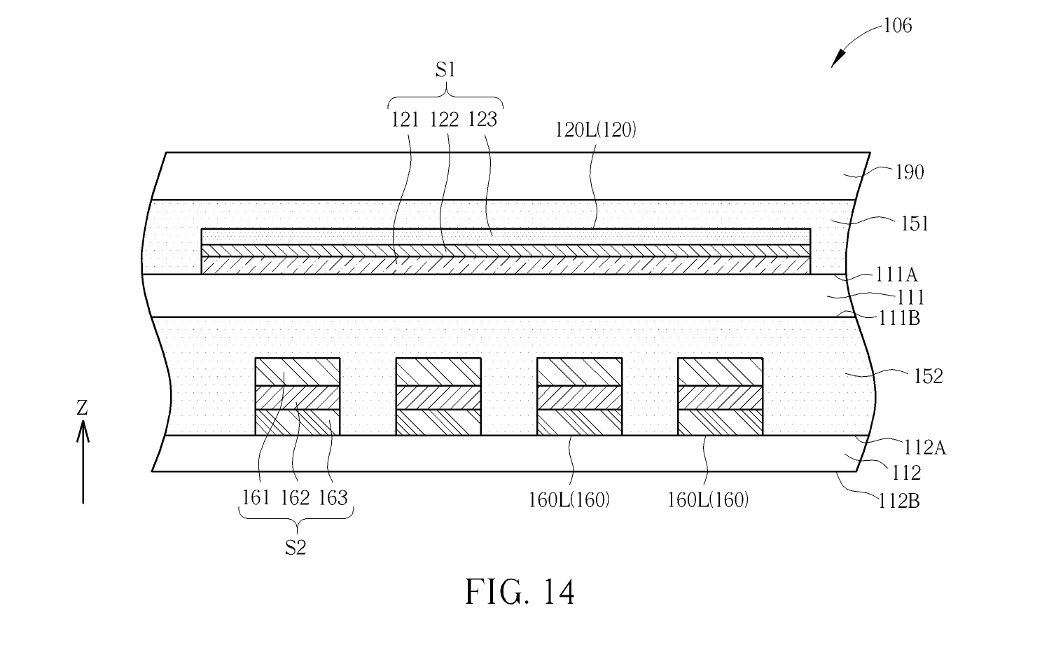

Please refer to FIG. 14. FIG. 14 is a schematic diagram illustrating a touch panel according to a sixth embodiment of the present invention. As shown in FIG. 14, the difference between the touch panel 106 of the sixth embodiment in the present invention and the touch panel of the preceding fifth embodiment is that the touch panel 106 further includes a second substrate 112, which is disposed opposite to the first substrate 111. The second substrate 112 has a first surface 112A and a second surface 112B opposite to the first surface 112A. The first surface 112A of the second substrate 112 faces the second surface 111B of the first substrate 111. In the touch panel 106, the second composite material conductive layer 160 is disposed on the second substrate 112. In other words, the first sensing electrodes 120L and the second sensing electrodes 160L are respectively disposed on the first substrate 111 and the second substrate 112. It is worth noting that, in this embodiment, the equivalent refraction index of the first composite material conductive layer 120 is substantially between the refraction index of the first substrate 111 and 1.1 times the refraction index of the first substrate 111. The equivalent refraction index of the second composite material conductive layer 160 is substantially between the refraction index of the second substrate 112 and 1.1 times the refraction index of the second substrate 112. However, the present invention is not limited to this. Moreover, the touch panel 106 may further include the adhesive layer 151, an adhesive layer 152 and the cover substrate 190. The adhesive layer 152 is disposed between the first substrate 111 and the second substrate 112 so as to attach the first substrate 111 to the second substrate 112. The adhesive layer 151 is disposed between the first substrate 111 and the cover substrate 190 so as to attach the first substrate 111 to the cover substrate 190. In this embodiment, the first composite material conductive layer 120 is disposed on the first surface 111A of the first substrate 111. The second composite material conductive layer 160 is disposed on the first surface 112A of the second substrate 112. Nevertheless, the present invention is not limited to this; in other embodiments of the present invention according to other considerations, the first composite material conductive layer 120 is disposed on the second surface 111B of the first substrate 111 and/or the second composite material conductive layer 160 is disposed on the second surface 112B of the second substrate 112 in order to achieve the desire combined effects of both the first sensing electrodes 120L and the second sensing electrodes 160L. Besides, since the first composite material conductive layer 120 and the second composite material conductive layer 160 are respectively disposed on different substrates, the overall fabrication processes may be simplified—the first sensing electrodes 120L and the second sensing electrodes 160L are respectively formed on a substrate comprising the first composite material conductive layer 120 and another substrate comprising the second composite material conductive layer 160 through different and separate patterning processes, such as lithography processes and etching processes, and then the two substrates adhere to each other with the adhesive layer 152. The second substrate 112 in this embodiment is preferably a plastic substrate, but not limited thereto.

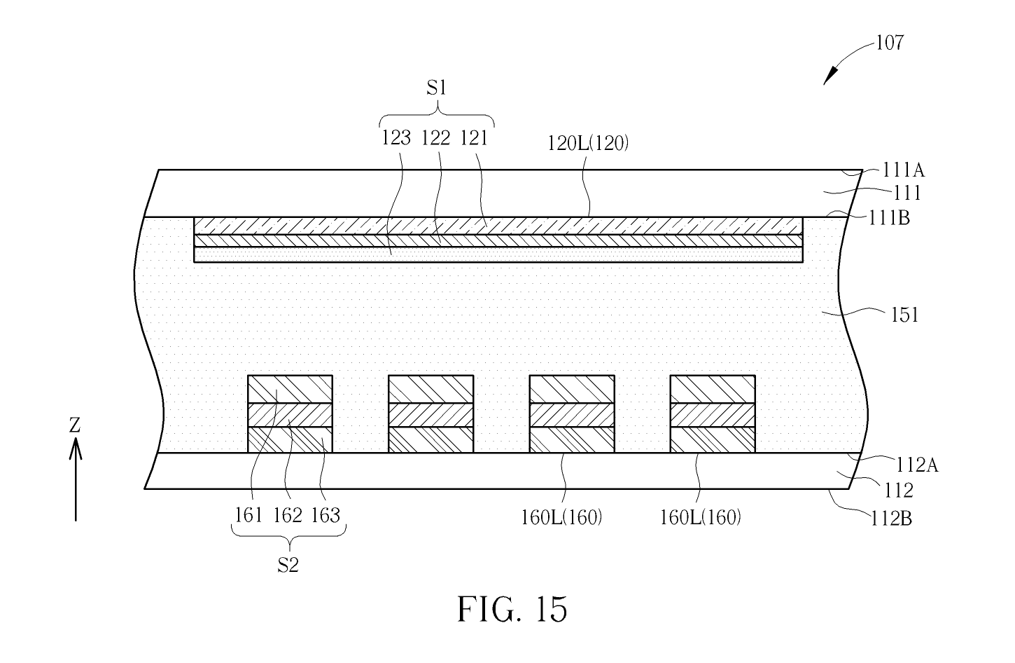

Please refer to FIG. 15. FIG. 15 is a schematic diagram illustrating a touch panel according to another embodiment of the present invention. As shown in FIG. 15, the difference between the touch panel 107 of this embodiment in the present invention and the touch panel of the preceding sixth embodiment is that the first composite material conductive layer 120 in the touch panel 107 is disposed on the second surface 111B of the first substrate 111 facing the second substrate 112. The second composite material conductive layer 160 is disposed on the first surface 112A of the second substrate 112 facing the first substrate 111. In other words, the first sensing electrodes 120L and the second sensing electrodes 160L are respectively disposed on the inner surface of the first substrate 111 and the inner surface of the second substrate 112. Then, the first substrate 111 adheres to the second substrate 112 with the adhesive layer 151. It is worth noting that, in this embodiment, the equivalent refraction index of the first composite material conductive layer 120 is substantially between the refraction index of the first substrate 111 and 1.1 times the refraction index of the first substrate 111. The equivalent refraction index of the second composite material conductive layer 160 is substantially between the refraction index of the second substrate 112 and 1.1 times the refraction index of the second substrate 112. However, the present invention is not limited to this. In addition, the first substrate 111 in this embodiment is preferably a cover lens or a cover glass, but not limited thereto. Furthermore, in other embodiments of the present invention, the second composite material conductive layer 160 may be disposed on the second surface 112B of the second substrate 112 without facing the first substrate 111 according to other considerations, but not limited thereto.

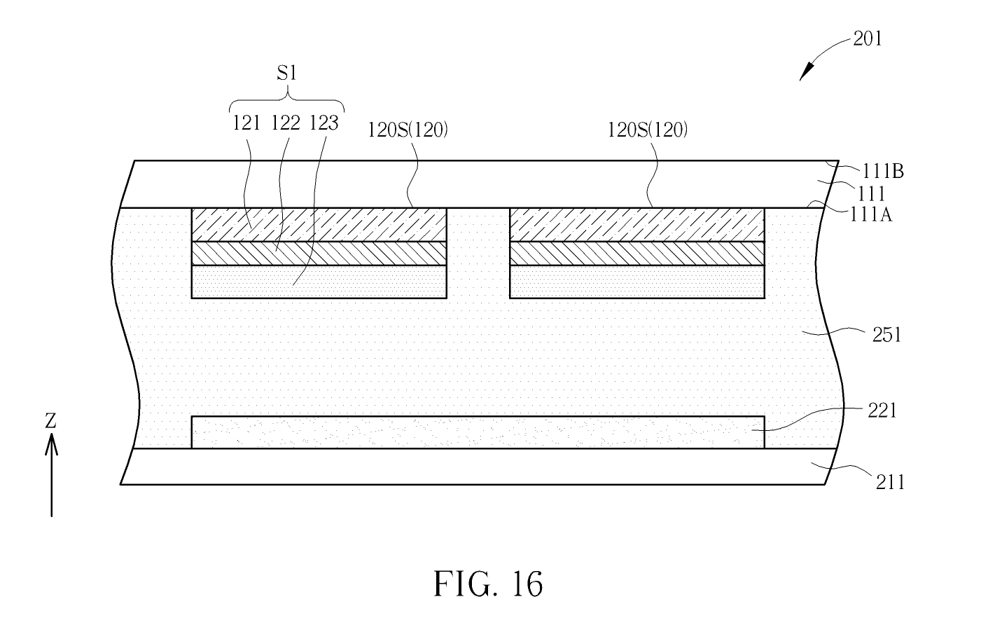

Please refer to FIG. 16. FIG. 16 is a schematic diagram illustrating a touch display device according to a seventh embodiment of the present invention. As shown in FIG. 16, the touch display device 201 of this embodiment includes the first substrate 111, a display substrate 211, a display unit 221 and the first composite material conductive layer 120. The display substrate 211 is disposed opposite to the first substrate 111. The display unit 221 is disposed on the display substrate 211. The first composite material conductive layer 120 is disposed on the first substrate 111. The first composite material conductive layer 120 includes a plurality of first sensing electrodes 120S. The first composite material conductive layer 120 has a first multilayer structure S1. The first multilayer structure S1 comprises a first refraction index compensating layer 121, a second refraction index compensating layer 123 and a first metal conductive layer 122. The first refraction index compensating layer 121, the first metal conductive layer 122 and the second refraction index compensating layer 123 are stacked in that order upward on the first substrate 111 so that the equivalent refraction index of the first composite material conductive layer 120 is substantially between the refraction index of the first substrate 111 and 1.1 times the refraction index of the first substrate 111. The refractive index of both the first refraction index compensating layer 121 and the second refraction index compensating layer 123 is preferably greater than the refractive index of the first metal conductive layer 122 so that the equivalent refraction index of the first composite material conductive layer 120 is substantially between the refraction index of the first substrate 111 and 1.1 times the refraction index of the first substrate 111, but not limited thereto. Besides, the thickness of the first refraction index compensating layer 121 is preferably in a range between 30 nm and 80 nm. The thickness of the second refraction index compensating layer 123 is preferably in a range between 30 nm and 80 nm. The thickness of first metal conductive layer 122 is preferably in a range between 5 nm and 20 nm. Nevertheless, the present invention is not limited to this. The refractive index of both the first refraction index compensating layer 121 and the second refraction index compensating layer 123 is preferably in a range between 1.5 and 3, although the exact thickness of the first refraction index compensating layer 121, the exact thickness of the second refraction index compensating layer 123 and the exact thickness of the first metal conductive layer 122 may be further modified according to other considerations so as to meet the required electrical properties and the required visual effect. For example, in one case, to improve the overall light transmittance of both the first substrate 111 and the first composite material conductive layer 120, the thicknesses of both the first refraction index compensating layer 121 and the second refraction index compensating layer 123 are respectively 50 nm. The thickness of the first metal conductive layer 122 is 10 nm. The coordinated thickness approaches of the layers in this embodiment have been detailed in the preceding embodiments, and will not be redundantly described. The first refraction index compensating layer 121 in this embodiment preferably comprises a transparent conductive layer, a transparent semiconductor layer or a transparent insulation layer. The second refraction index compensating layer 123 also preferably comprises a transparent conductive layer, a transparent semiconductor layer or a transparent insulation layer. Accordingly, the combined effects of the first refraction index compensating layer 121, the second refraction index compensating layer 123 and the first metal conductive layer 122 may effectively reduce the electrical impedance and improve the light transmittance. The features of the first composite material conductive layer 120 in this embodiment have been detailed in the first embodiment, and will not be redundantly described. It is worth noting that the display unit 221 in this embodiment may preferably include an organic light emitting diode (OLED). Preferably, the touch display device 201 in this embodiment may further include a sealant 251 disposed between the first substrate 111 and the display substrate 211. The sealant 251 is used to cover and seal the display unit 221. Therefore, the first substrate 111 in this embodiment may preferably include an encapsulation cover substrate, but not limited thereto. In other words, the touch display device 201 may be regarded as an in-cell touch display device. Since the first sensing electrodes 120S are formed out of the first composite material conductive layer 120, the heat resistance (ability to withstand high temperatures) requirement of the first substrate 111, which serves as the encapsulation cover substrate of the touch display device 201, is lower and the choice for the material of the touch display device 201 becomes wider. Furthermore, in other embodiments of the present invention, the first composite material conductive layer 120 may be disposed on the display substrate 211, for example, but not limited to, an array substrate, so as to form the required components on the display substrate 211 according other considerations.

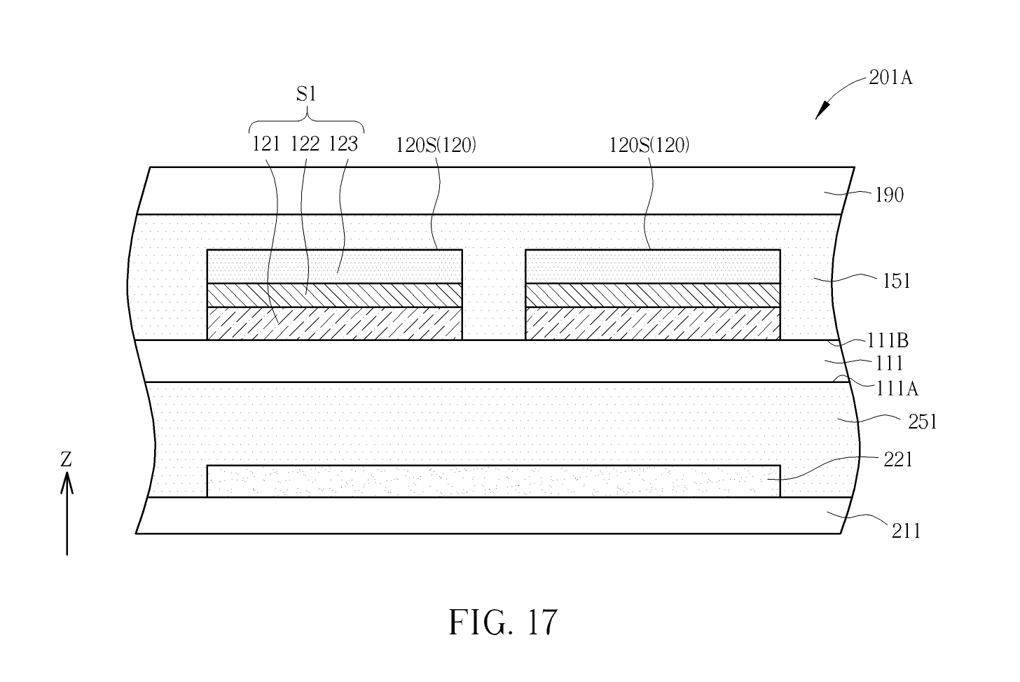

Please refer to FIG. 17. FIG. 17 is a schematic diagram illustrating a touch display device according to another embodiment of the present invention. As shown in FIG. 17, the difference between the touch display device 201A of this embodiment in the present invention and the touch display device of the preceding seventh embodiment is that the first composite material conductive layer 120 of this embodiment is disposed on the second surface 111B of the first substrate 111 not facing the display substrate 211. Moreover, the touch display device 201A further comprises the cover substrate 190 and the adhesive layer 151 disposed on a side of the second surface 111B. The adhesive layer 151 is disposed between the cover substrate 190 and the first substrate 111 so as to attach the cover substrate 190 to the first substrate 111. Apart from the cover substrate 190, the adhesive layer 151 and the location of the first composite material conductive layer 120 in the touch display device 201A of this embodiment, features, locations and material properties of other components in this embodiment are similar to those in the seventh embodiment detailed above and will not be redundantly described.

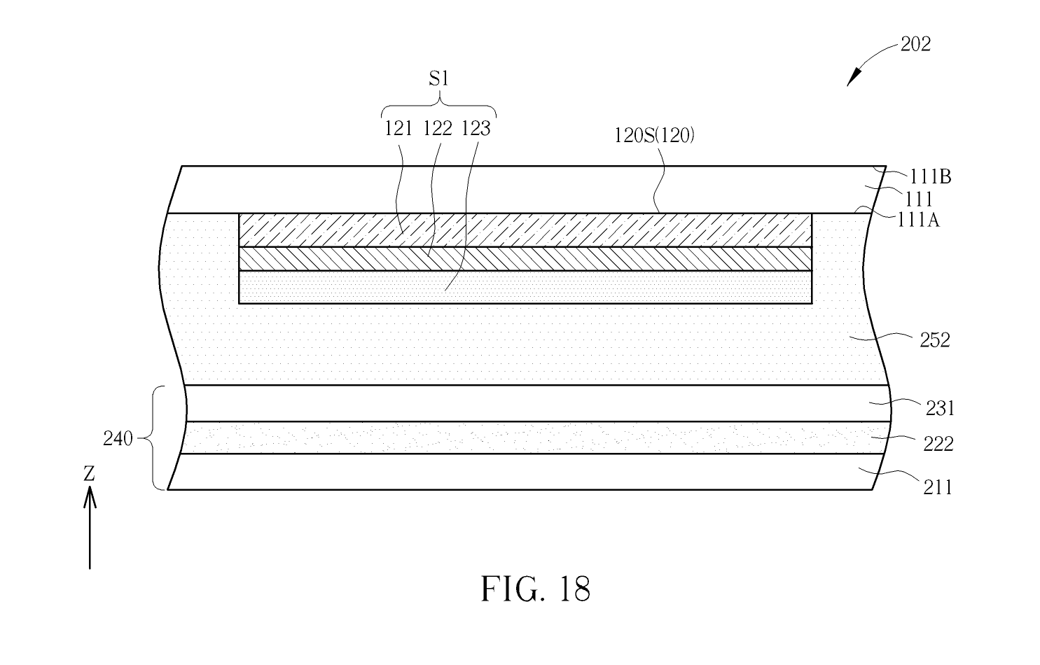

Please refer to FIG. 18. FIG. 18 is a schematic diagram illustrating a touch display device according to an eighth embodiment of the present invention. As shown in FIG. 18, the difference between the touch display device 202 of this embodiment in the present invention and the touch display device of the preceding seventh embodiment is that the touch display device 202 includes the first substrate 111, the display substrate 211, a display unit 222, the first composite material conductive layer 120, an adhesive layer 252 and a display upper substrate. The display upper substrate 231 is disposed between the first substrate 111 and the display substrate 211. The display unit 222 is disposed between the display substrate 211 and the display upper substrate 231 to form the display panel 240. The display unit 222 in this embodiment may preferably include a liquid crystal display unit, an organic light emitting diode display unit, an electro-wetting display unit, an e-ink display unit, a plasma display unit, a field emission display unit or other suitable display units. The display panel 240 may preferably include a liquid crystal display panel, an organic light emitting diode display panel, an electro-wetting display panel, an e-ink display panel, a plasma display panel, a field emission display unit or other suitable display panels, but not limited thereto. The adhesive layer 252 is disposed between the first substrate 111 and the display upper substrate 231 so as to attach the display panel 240 to the first substrate 111 with the first sensing electrodes 120S disposed. The first substrate 111 in this embodiment may preferably include a protective substrate or a cover glass, but not limited thereto. Moreover, the display panel 240 of other embodiments in the present invention may be combined with the touch panel in the preceding embodiments in order to form the touch display device.

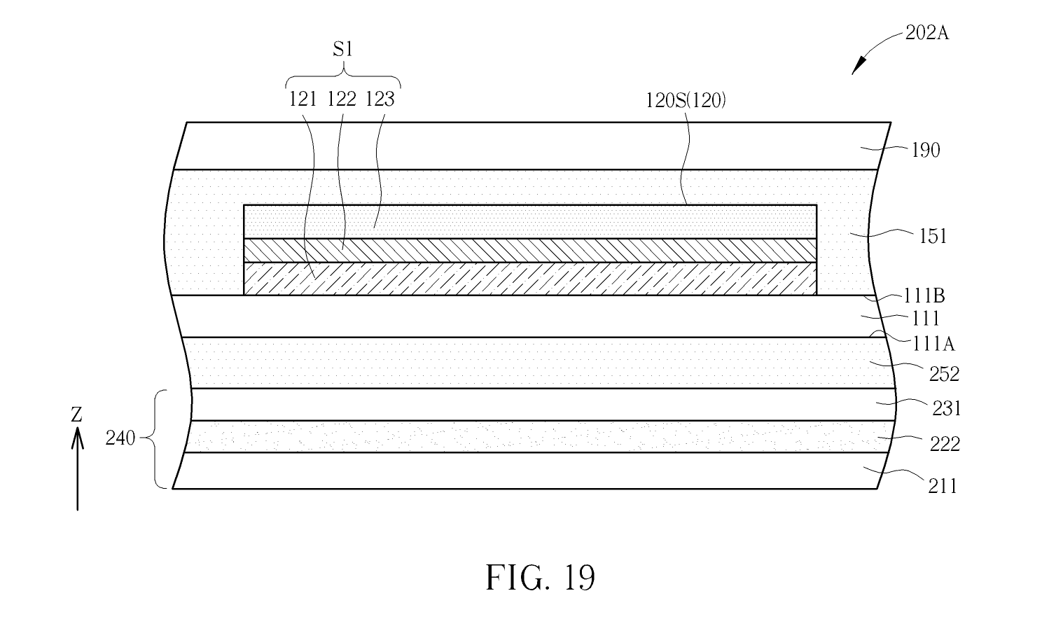

Please refer to FIG. 19. FIG. 19 is a schematic diagram illustrating a touch display device according to another embodiment of the present invention. As shown in FIG. 19, the difference between the touch display device 202A of this embodiment in the present invention and the touch display device of the preceding eighth embodiment is that the first composite material conductive layer 120 of this embodiment is disposed on the second surface 111B of the first substrate 111 not facing the display panel 240. Moreover, the touch display device 202A further comprises the cover substrate 190 and the adhesive layer 151 disposed on a side of the second surface 111B. The adhesive layer 151 is disposed between the cover substrate 190 and the first substrate 111 so as to attach the cover substrate 190 to the first substrate 111. Apart from the cover substrate 190, the adhesive layer 151 and the location of the first composite material conductive layer 120 in the touch display device 202A of this embodiment, features, locations and material properties of other components in this embodiment are similar to those in the eighth embodiment detailed above and will not be redundantly described.

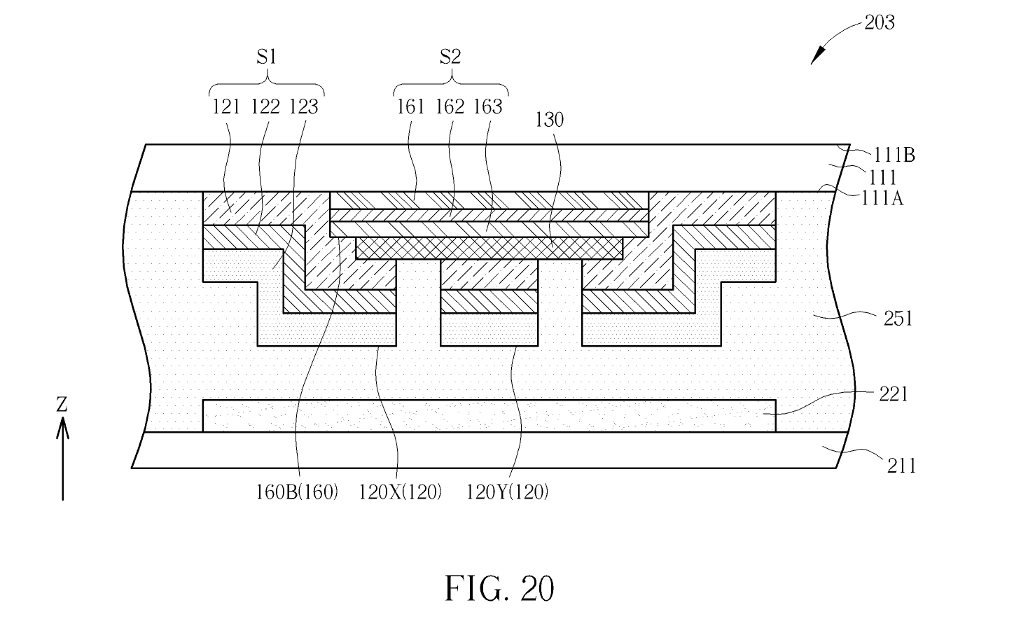

Please refer to FIG. 20. FIG. 20 is a schematic diagram illustrating a touch display device according to a ninth embodiment of the present invention. As shown in FIG. 20, the difference between the touch display device 203 of the ninth embodiment and the touch display device of the seventh embodiment is that the touch display device 203 further includes a second composite material conductive layer 160. The second composite material conductive layer 160 is disposed on the first substrate 111. The second composite material conductive layer 160 has a second multilayer structure S2. The second multilayer structure S2 comprises a third refraction index compensating layer 161, a fourth refraction index compensating layer 163 and a second metal conductive layer 162. The second metal conductive layer 162 is disposed between the third refraction index compensating layer 161 and the fourth refraction index compensating layer 163 so that the equivalent refraction index of the second composite material conductive layer 160 is substantially between the refraction index of the first substrate 111 and 1.1 times the refraction index of the first substrate 111. The features of the second composite material conductive layer 160 in this embodiment have been detailed in the preceding embodiments, and will not be redundantly described. In this embodiment, both the first composite material conductive layer 120 and the second composite material conductive layer 160 are disposed on the same side of the first substrate 111. The second composite material conductive layer 160 is disposed between the first substrate 111 and the first composite material conductive layer 120. In this embodiment, the structure is formed on the first substrate 111 to ensure the touch sensing function and is similar to that of the above-mentioned third embodiment, and will not be redundantly described.

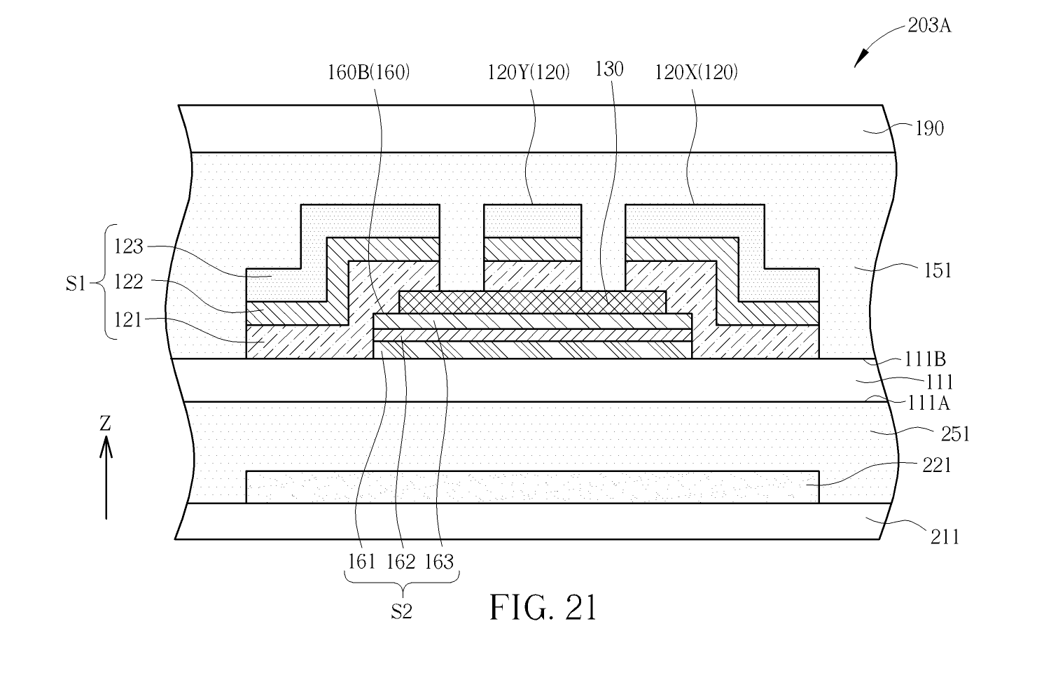

Please refer to FIG. 21. FIG. 21 is a schematic diagram illustrating a touch display device according to another embodiment of the present invention. As shown in FIG. 21, the difference between the touch display device 203A of this embodiment in the present invention and the touch display device of the preceding ninth embodiment is that the first composite material conductive layer 120 of this embodiment is disposed on the second surface 111B of the first substrate 111 not facing display substrate 211. Moreover, the touch display device 203A further comprises the cover substrate 190 and the adhesive layer 151 disposed on a side of the second surface 111B. The adhesive layer 151 is disposed between the cover substrate 190 and the first substrate 111 so as to attach the cover substrate 190 to the first substrate 111. Apart from the cover substrate 190, the adhesive layer 151 and the location of the first composite material conductive layer 120 in the touch display device 203A of this embodiment, features, locations and material properties of other components in this embodiment are similar to those in the ninth embodiment detailed above and will not be redundantly described.

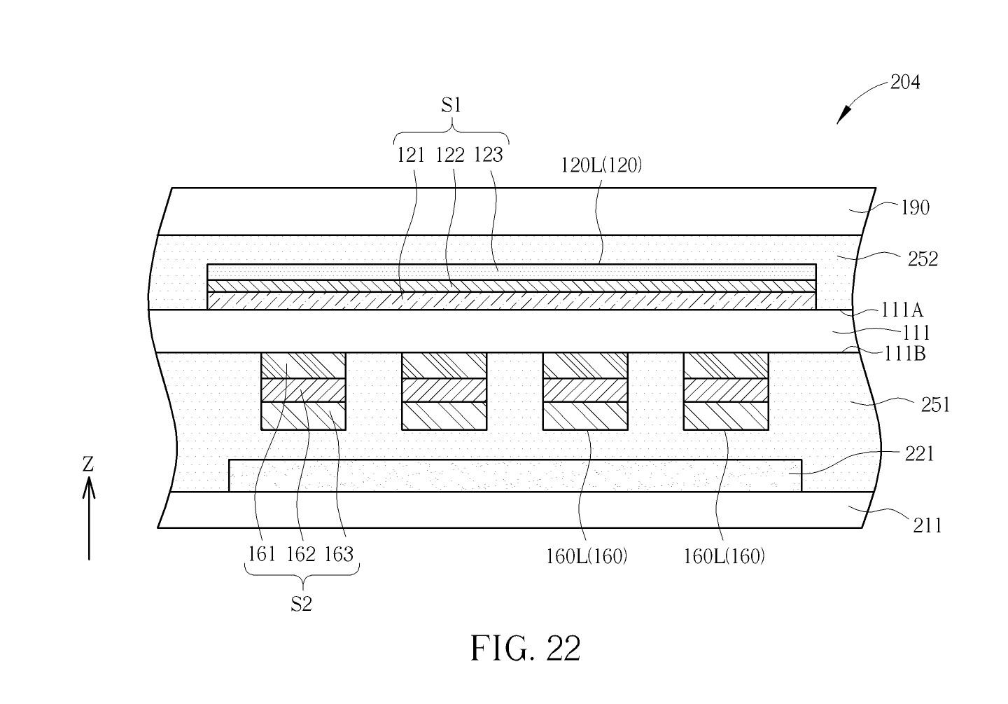

Please refer to FIG. 22. FIG. 22 is a schematic diagram illustrating a touch display device according to a tenth embodiment of the present invention. As shown in FIG. 22, the difference between the touch display device 204 of the tenth embodiment in the present invention and the touch display device of the preceding ninth embodiment is that, in the touch display device 204, the first composite material conductive layer 120 and the second composite material conductive layer 160 are respectively disposed on the two opposite sides of the first substrate 111. To be more specifically, the first composite material conductive layer 120 is disposed on the first surface 111A of the first substrate 111. The second composite material conductive layer 160 is disposed on the second surface 111B of the first substrate 111. In addition, the first composite material conductive layer 120 includes a plurality of first sensing electrodes 120L. The second composite material conductive layer 160 includes a plurality of second sensing electrodes 160L. In this embodiment, the touch display device 204 may further comprise an adhesive layer 252 and the cover substrate 190, which are disposed on a side of the first surface 111A of the first substrate 111. The adhesive layer 252 is disposed between the first substrate 111 and the cover substrate 190 so as to attach the first substrate 111 to the cover substrate 190. Apart from the cover substrate 190, the adhesive layer 252 and the location of the second composite material conductive layer 160 in the touch display device 204 of this embodiment, features, locations and material properties of other components in this embodiment are similar to those in the ninth embodiment detailed above and will not be redundantly described.

To sum up, in the touch panel and the touch display device of the present invention, since sensing electrodes are formed from a composite material conductive layer, which comprises two metal conductive layers and a refraction index compensating layer in between (i.e., the refraction index compensating layer between the two metal conductive layers), the resistance is effectively reduced and the light transmittance is improved, even when processed with relatively low temperature processes. Moreover, the choice for the substrates' material of the touch panel and the touch display device becomes wider.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A touch panel, comprising:
a first substrate; and
a first composite material conductive layer, disposed on the first substrate, the first composite material conductive layer comprising a plurality of first sensing electrodes, wherein the first composite material conductive layer has a first multilayer structure, and the first multilayer structure comprises a first refraction index compensating layer, a second refraction index compensating layer, and a first metal conductive layer, wherein the first refraction index compensating layer, the first metal conductive layer, and the second compensation layer are stacked on the first substrate, and an equivalent refraction index of the first composite material conductive layer is substantially between a refraction index of the first substrate and 1.1 times the refraction index of the first substrate.

2. The touch panel according to claim 1, wherein the first metal conductive layer is disposed between the first refraction index compensating layer and the second refraction index compensating layer, and the first refraction index compensating layer, the first metal conductive layer and the second refraction index compensating layer are stacked on the first substrate.

3. The touch panel according to claim 1, wherein a thickness of the first refraction index compensating layer is in a range between 30 nanometers and 80 nanometers, a thickness of the second refraction index compensating layer is in a range between 30 nanometers and 80 nanometers, and a thickness of the first metal conductive layer is in a range between 5 nanometers and 20 nanometers.

4. The touch panel according to claim 3, wherein a thickness of the first refraction index compensating layer is 50 nanometers, a thickness of the second refraction index compensating layer is 50 nanometers, and a thickness of the first metal conductive layer is 10 nanometers.

5. The touch panel according to claim 1, wherein a refraction index of the first refraction index compensating layer and a refraction index of the second refraction index compensating layer are respectively greater than a refraction index of the first metal conductive layer.

6. The touch panel according to claim 1, wherein the first refraction index compensating layer comprises a transparent conductive layer, a transparent semiconductor layer or a transparent insulation layer.

7. The touch panel according to claim 1, wherein the second refraction index compensating layer comprises a transparent conductive layer, a transparent semiconductor layer or a transparent insulation layer.

8. The touch panel according to claim 1, wherein the touch panel has a touch sensing region and a peripheral region disposed on at least one side of the touch sensing region, and a decoration layer is formed in the peripheral region on the first substrate.

9. The touch panel according to claim 1, wherein the first composite material conductive layer further comprises a plurality of trace lines disposed in a peripheral region, and each of the trace lines is electrically connected to each of the first sensing electrodes.

10. The touch panel according to claim 1, wherein the first substrate comprises a plastic substrate or a cover glass.

11. The touch panel according to claim 1, further comprising a second composite material conductive layer, wherein the second composite material conductive layer has a second multilayer structure, the second multilayer structure comprises a third refraction index compensating layer, a fourth refraction index compensating layer and a second metal conductive layer, the second metal conductive layer is disposed between the third refraction index compensating layer and the fourth refraction index compensating layer, and the third refraction index compensating layer, the second metal conductive layer and the fourth refraction index compensating layer are mutually stacked.

12. The touch panel according to claim 11, wherein a thickness of the third refraction index compensating layer is in a range between 30 nanometers and 80 nanometers, a thickness of the fourth refraction index compensating layer is in a range between 30 nanometers and 80 nanometers, and a thickness of the second metal conductive layer is in a range between 5 nanometers and 20 nanometers.

13. The touch panel according to claim 12, wherein a thickness of the third refraction index compensating layer is 50 nanometers, a thickness of the fourth refraction index compensating layer is 50 nanometers, and a thickness of the second metal conductive layer is 10 nanometers.

14. The touch panel according to claim 11, wherein the first composite material conductive layer and the second composite material conductive layer are disposed on the same side of the first substrate.

15. The touch panel according to claim 11, wherein the first composite material conductive layer and the second composite material conductive layer are respectively disposed on different sides of the first substrate, and the second composite material conductive layer comprises a plurality of second sensing electrodes.

16. The touch panel according to claim 11, further comprising a second substrate disposed opposite to the first substrate, wherein the second composite material conductive layer is disposed on the second substrate, and the second composite material conductive layer comprises a plurality of second sensing electrodes.

17. A touch display device, comprising:
a first substrate;
a display substrate, disposed opposite to the first substrate;
a display unit, disposed on the display substrate; and
a first composite material conductive layer, disposed on the first substrate, the first composite material conductive layer comprising a plurality of first sensing electrodes, wherein the first composite material conductive layer has a first multilayer structure, and the first multilayer structure comprises a first refraction index compensating layer, a second refraction index compensating layer, and a first metal conductive layer, wherein the first refraction index compensating layer, the first metal conductive layer, and the second compensation layer are stacked on the first substrate, and an equivalent refraction index of the first composite material conductive layer is substantially between a refraction index of the first substrate and 1.1 times the refraction index of the first substrate.

18. The touch display device according to claim 17, wherein the first metal conductive layer is disposed between the first refraction index compensating layer and the second refraction index compensating layer, and the first refraction index compensating layer, the first metal conductive layer and the second refraction index compensating layer are stacked on the first substrate.

19. The touch display device according to claim 17, wherein a thickness of the first refraction index compensating layer is in a range between 30 nanometers and 80 nanometers, a thickness of the second refraction index compensating layer is in a range between 30 nanometers and 80 nanometers, and a thickness of the first metal conductive layer is in a range between 5 nanometers and 20 nanometers.

20. The touch display device according to claim 19, wherein a thickness of the first refraction index compensating layer is 50 nanometers, a thickness of the second refraction index compensating layer is 50 nanometers, and a thickness of the first metal conductive layer is 10 nanometers.

21. The touch display device according to claim 17, wherein a refraction index of the first refraction index compensating layer and a refraction index of the second refraction index compensating layer are respectively greater than a refraction index of the first metal conductive layer.

22. The touch display device according to claim 17, wherein the first refraction index compensating layer comprises a transparent conductive layer, a transparent semiconductor layer or a transparent insulation layer.

23. The touch display device according to claim 17, wherein the second refraction index compensating layer comprises a transparent conductive layer, a transparent semiconductor layer or a transparent insulation layer.

24. The touch display device according to claim 17, wherein the first substrate comprises an encapsulation cover substrate.

25. The touch display device according to claim 17, wherein the display unit comprises a liquid crystal display unit, an organic light-emitting diode display unit, an electro-wetting display unit, an e-ink display unit, a plasma display unit or a field emission display (FED) unit.

26. The touch display device according to claim 17, further comprising a sealant disposed between the first substrate and the display substrate, wherein the sealant covers the display unit.

27. The touch display device according to claim 17, further comprising a second composite material conductive layer, wherein the second composite material conductive layer has a second multilayer structure, the second multilayer structure comprises a third refraction index compensating layer, a fourth refraction index compensating layer and a second metal conductive layer; the second metal conductive layer is disposed between the third refraction index compensating layer and the fourth refraction index compensating layer, and the third refraction index compensating layer, the second metal conductive layer and the fourth refraction index compensating layer are mutually stacked.

28. The touch display device according to claim 27, wherein a thickness of the third refraction index compensating layer is in a range between 30 nanometers and 80 nanometers, a thickness of the fourth refraction index compensating layer is in a range between 30 nanometers and 80 nanometers, and a thickness of the second metal conductive layer is in a range between 5 nanometers and 20 nanometers.

29. The touch display device according to claim 27, wherein a thickness of the third refraction index compensating layer is 50 nanometers, a thickness of the fourth refraction index compensating layer is 50 nanometers, and a thickness of the second metal conductive layer is 10 nanometers.

30. The touch display device according to claim 27, wherein the first composite material conductive layer and the second composite material conductive layer are disposed on the same side of the first substrate.

31. The touch display device according to claim 27, wherein the first composite material conductive layer and the second composite material conductive layer are respectively disposed on different sides of the first substrate, and the second composite material conductive layer comprises a plurality of second sensing electrodes.

32. A touch panel, comprising:
a first substrate; and
a first composite material conductive layer, disposed on the first substrate, the first composite material conductive layer comprising a plurality of first sensing electrodes, wherein the first composite material conductive layer has a first multilayer structure, and the first multilayer structure comprises a first refraction index compensating layer and a first metal conductive layer, wherein the first refraction index compensating layer and the first metal conductive layer are stacked on the first substrate, a thickness of the first refraction index compensating layer is in a range between 30 nanometers and 80 nanometers, and a thickness of the first metal conductive layer is in a range between 5 nanometers and 20 nanometers.

33. The touch panel according to claim 32, wherein the first refraction index compensating layer is disposed between the first substrate and the first metal conductive layer, the thickness of the first refraction index compensating layer is 60 nanometers, and the thickness of the first metal conductive layer is 10 nanometers.

34. The touch panel according to claim 32, wherein the first metal conductive layer is disposed between the first substrate and the first refraction index compensating layer, the thickness of the first refraction index compensating layer is 40 nanometers, and the thickness of the first metal conductive layer is 10 nanometers.
